(19) United States
(12) Patent Application Publication
(10) Pub. No.: US 2015/0364663 A1
(43) Pub. Date: Dec. 17, 2015

(54) LIGHT-EMITTING DEVICE AND METHOD OF MANUFACTURING THE SAME

(71) Applicant: TOYODA GOSEI CO., LTD., Kiyosu-shi (JP)

(72) Inventors: Yuta MORIMURA, Kiyosu-shi (JP); Hiroyuki TAJIMA, Kiyosu-shi (JP); Yuhki ITO, Kiyosu-shi (JP)

(21) Appl. No.: 14/724,685

(22) Filed: May 28, 2015

(30) Foreign Application Priority Data
Jun. 12, 2014 (JP) 2014-121646

(51) Int. Cl. H01L 33/62; H01L 33/00; H01L 33/56; H01L 27/15

(52) U.S. Cl. CPC H01L 33/62; H01L 27/15; H01L 33/005; H01L 33/56; H01L 2933/0033; H01L 2933/0066

(57) ABSTRACT

A light-emitting device includes a case including a recessed portion, a lead frame that is integrally molded with the case so as to be exposed on a bottom of the recessed portion and that includes separated first and second regions, a conductive paste film formed on the bottom of the recessed portion in a region between the first and second regions, a first flip-chip light-emitting element including first and second electrodes that are electrically connected to the first region and the conductive paste film, respectively, and a second flip-chip light-emitting element including third and fourth electrodes that are electrically connected to the second region and the conductive paste film, respectively.

The present application is based on Japanese patent application No.2014-121646 filed on Jun. 12, 2014, the entire contents of which are incorporated herein by reference.

### BACKGROUND OF THE INVENTION

1. Field of the Invention

The invention relates to a light-emitting device and a method of manufacturing the light-emitting device.

2. Description of the Related Art

A side-view light-emitting device is known in which two LED chips are disposed in a case molded integrally with a lead frame (see e.g. JP-A-2010-130008). The light-emitting device disclosed in JP-A-2010-130008 is provided with a lead frame having three separate regions separated in a longitudinal direction. The LED chips are each mounted on the both side regions of the lead frame and each LED chip is connected to the middle region of the lead frame via a bonding wire.

Also, a light-emitting device is known in which LED elements are connected to electrode terminals via metal paste (see e.g. JP-A-2005-12240).

### SUMMARY OF THE INVENTION

It is an object of the invention to provide a thin light-emitting device that is equipped with plural light-emitting elements mounted in a case molded integrally with a lead frame and has a small size relative to the light-emitting elements, as well as a method of manufacturing the light-emitting device.
(1) According to one embodiment of the invention, a light-emitting device comprises:

a case comprising a recessed portion;

a lead frame that is integrally molded with the case so as to be exposed on a bottom of the recessed portion and that comprises separated first and second regions;

a conductive paste film formed on the bottom of the recessed portion in a region between the first and second regions;

a first flip-chip light-emitting element comprising first and second electrodes that are electrically connected to the first region and the conductive paste film, respectively; and

a second flip-chip light-emitting element comprising third and fourth electrodes that are electrically connected to the second region and the conductive paste film, respectively.

In the above embodiment (1) of the invention, the following modifications and changes can be made.

(i) The first electrode is connected to the first region and the third electrode to the second region via the conductive paste film, and wherein the second and fourth electrodes are directly connected to the conductive paste film.

(ii) The case comprises a thermoplastic resin.

(iii) A rugged pattern is formed on the bottom of the recessed portion in a region in contact with the conductive paste film.

(2) According to another embodiment of the invention, a method of manufacturing a light-emitting device comprises:

molding a case comprising a recessed portion integrally with a lead frame included in a metal frame and comprising separated first and second regions such that the first and second regions are exposed on a bottom of the recessed portion;

forming a conductive paste film on the bottom of the recessed portion in a region between the first and second regions;

mounting a first flip-chip light-emitting element comprising first and second electrodes such that the first and second electrodes are electrically connected to the first region and the conductive paste film, respectively;

mounting a second flip-chip light-emitting element comprising third and fourth electrodes so that the third and fourth electrodes are electrically connected to the second region and the conductive paste film, respectively; and

separating the first and second regions of the lead frame from the metal frame.

In the above embodiment (2) of the invention, the following modifications and changes can be made.

(iv) The mounting of the first and second flip-chip light-emitting elements is conducted such that the first electrode is connected to the first region and the third electrode to the second region via conductive paste and the second and fourth electrodes are directly connected to the conductive paste film.

(v) The case comprises a thermoplastic resin.

(vi) A rugged pattern is formed on the bottom of the recessed portion in a region in contact with the conductive paste film.

### Effects of the Invention

According to one embodiment of the invention, a thin light-emitting device can be provided that is equipped with plural light-emitting elements mounted in a case molded integrally with a lead frame and has a small size relative to the light-emitting elements, as well as a method of manufacturing the light-emitting device.

### BRIEF DESCRIPTION OF THE DRAWINGS

Next, the present invention will be explained in more detail in conjunction with appended drawings, wherein:

FIG. 1 is a vertical cross-sectional view showing a light-emitting device in an embodiment according to the invention;

FIG. 2A is a top view showing the light-emitting device in the embodiment wherein a case and a sealing material are not shown;

FIG. 2B is a top view showing a metal frame before separating a lead frame in the embodiment;

FIG. 3 is a vertical cross-sectional view showing a light-emitting device in Comparative Example in which a lead frame has three separate regions;

FIG. 4A is a top view showing the light-emitting device in Comparative Example wherein the case and the sealing material are not shown; and

FIG. 4B is a top view showing a metal frame before separating a lead frame in Comparative Example.

### DETAILED DESCRIPTION OF THE PREFERRED EMBODIMENTS

### Embodiment

### Configuration of Light-Emitting Device

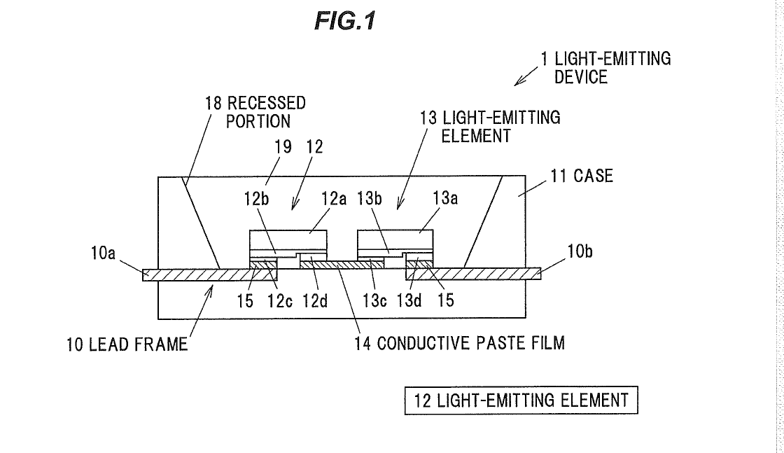

FIG. 1 is a vertical cross-sectional view showing a light-emitting device 1 in the embodiment.

The light-emitting device 1 has a case 11 having a recessed portion 18, a lead frame 10 which is integrally molded into the case 11 so as to be exposed on a bottom of the recessed portion 18 and has separated first and second regions 10a and 10b, a conductive paste film 14 formed on the bottom of the recessed portion 18 in a region between the first region 10a and the second region 10b, a flip-chip light-emitting element 12 (i.e., first light-emitting element) having electrodes 12c and 12d which are respectively electrically connected to the first region 10a and the conductive paste film 14, a flip-chip light-emitting element 13 (i.e., second light-emitting element) having electrodes 13d and 13c which are respectively electrically connected to the second region 10b and the conductive paste film 14, and a sealing material 19 filled inside the recessed portion 18 to seal the light-emitting elements 12 and 13.

The light-emitting device 1 is a thin light-emitting device such as of a side-view type, and the lead frame 10 and the case 11 have a substantially rectangular shape in a plan view.

The entire lead frame 10 or the surface thereof is formed of a conductive material such as Ag, Cu or Al.

The case 11 is formed of e.g., a thermoplastic resin such as polyphthalamide resin, LCP (Liquid Crystal Polymer) or PCT (Polycyclohexylene Dimethylene Terephalate), or a thermosetting resin such as silicone resin, modified silicone resin, epoxy resin or modified epoxy resin. The case 11 may contain light-reflecting particles of titanium dioxide, etc., to improve light reflectance.

The case 11 is molded integrally with the lead frame 10 by, e.g., insert molding which is performed by injecting a resin into a mold having the lead frame 10 already inserted therein.

The recessed portion 18 of the case 11 has a substantially rectangular shape in a plan view. Here, a length in a longitudinal direction of the substantially rectangular shape is called a width of the light-emitting device 1 and a length in a lateral direction is called thickness of the light-emitting device 1.

The light-emitting elements 12 and 13 respectively have chip substrates 12a and 13a and crystal layers 12b and 13b each including a light-emitting layer. The light-emitting elements 12 and 13 are flip-chip light-emitting elements in which the electrodes 12c, 12d, 13c and 13d face downward. The light-emitting elements 12 and 13 are, e.g., LED chips or laser diode chips.

In the light-emitting element 12, one of the electrodes 12c and 12d is an n-side electrode and another is a p-side electrode. Likewise, in the light-emitting element 13, one of the electrodes 13c and 13d is an n-side electrode and another is a p-side electrode.

The conductive paste film 14 is a film formed of conductive paste as a mixture of a conductive material such as Au, Ag or Cu with a resin such as epoxy resin. The conductive paste film 14 can be formed by potting, dispensing, jet-dispensing or stamping, etc.

As shown in FIG. 1, it is possible to directly connect the electrode 12d of the light-emitting element 12 and the electrode 13c of the light-emitting element 13 to the conductive paste film 14. Then, in the example shown in FIG. 1, the electrode 12c of the light-emitting element 12 is connected to the first region 10a of the lead frame 10 and the electrode 13d of the light-emitting element 13 to the second region 10b of the lead frame 10 via conductive paste 15. In this case, high-temperature processing such as soldering is not required for mounting the light-emitting elements 12 and 13 since it is possible to harden the conductive paste at a temperature of about 150° C. Therefore, a wide range of materials can be used to form the case 11 and it is even possible to use, e.g., a thermoplastic resin to form the case 11.

A rugged pattern (surface texturing) may be formed on the bottom of the recessed portion 18 of the case 11 in a region in contact with the conductive paste film 14. In this case, adhesion of the conductive paste film 14 to the case 11 is increased. Therefore, even if the conductive paste film 14 is formed of, e.g., conductive paste requiring sintering for use, separation of the conductive paste film 14 from the case 11 after sintering is prevented.

The sealing material 19 is formed of, e.g., a transparent resin such as silicone-based resin or epoxy-based resin. In addition, the sealing resin 19 may contain phosphor in the form of particles. For example, when emission color of the light-emitting elements 12 and 13 is blue and fluorescence color of the phosphor contained in the sealing resin 19 is yellow, emission color of the light-emitting device 1 is white.

Edges of the lead frame 10 in a longitudinal direction (in a width direction of the light-emitting device 1), i.e., edges of the first region 10a and the second region 10b on the outer side of the light-emitting device 1, penetrate through the sidewalls of the case 11 and protrude to the outside of the case 11. The protruding portions of the lead frame 10 are the areas which are cut for separating the lead frame 10 from a metal frame including the lead frame 10. The lead frame 10 is separated from the metal frame after the lead frame 10 is integrally molded into the case 11 and the light-emitting device 1 is formed.

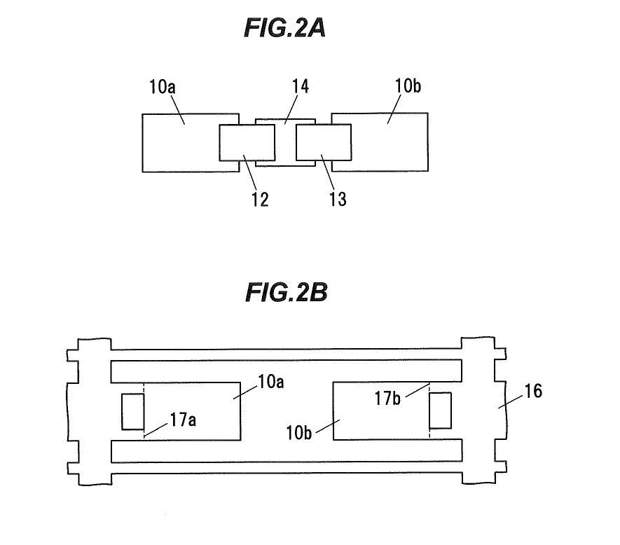

FIG. 2A is a top view showing the light-emitting device 1 wherein the case 11 and the sealing material 19 are not shown. FIG. 2B is a top view showing a metal frame 16 before separating the lead frame 10.

After the light-emitting device 1 is formed, the first region 10a and the second region 10b of the lead frame 10 are separated from the metal frame 16 respectively along cut sections 17a and 17b indicated by dotted-lines in FIG. 2B. As described above, a portion of the first region 10a in the vicinity of the cut section 17a and a portion of the second region 10b in the vicinity of the cut section 17b protrude to the outside of the case 11.

The cut sections 17a and 17b are provided at edges of the lead frame 10 in the longitudinal direction (in the width direction of the light-emitting device 1) because providing the cut sections 17a and 17b at edges of the lead frame 10 in the lateral direction (in the thickness direction of the light-emitting device 1) causes an increase in thickness of the light-emitting device 1 which is of, e.g., a side-view type required to be thin.

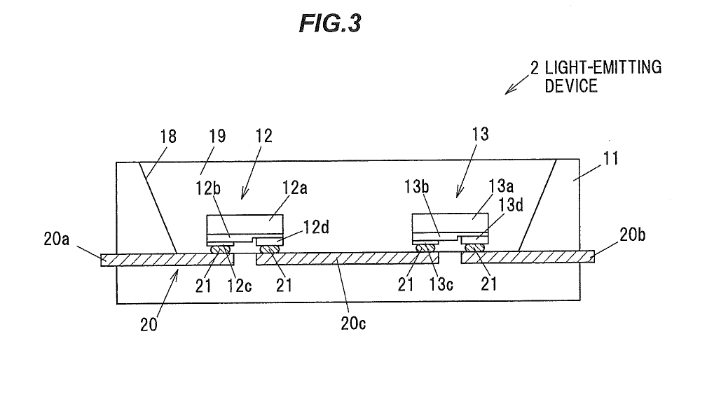

FIG. 3 is a vertical cross-sectional view showing a light-emitting device 2 as Comparative Example in which a lead frame 20 has three separate regions.

The light-emitting device 2 is different from the light-emitting device 1 of the present invention in that the lead frame 20 includes a first region 20a, a second region 20b and a third region 20c located therebetween and that the light-emitting elements 12 and 13 are connected to the lead frame 20 via conductive bumps 21.

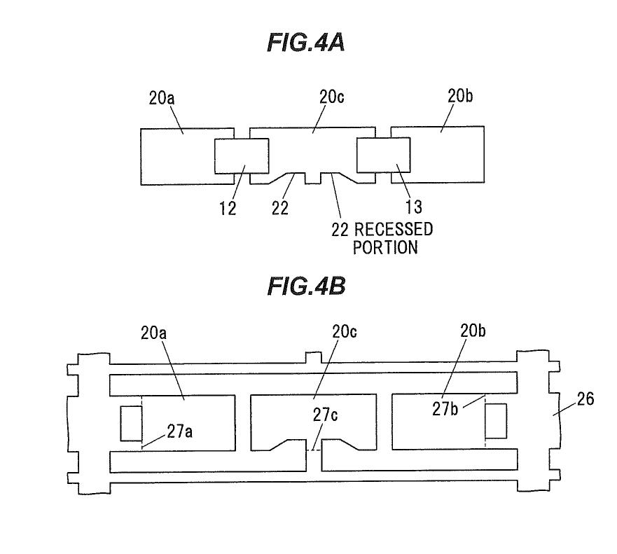

FIG. 4A is a top view showing the light-emitting device 2 wherein the case 11 and the sealing material 19 are not shown. FIG. 4B is a top view showing a metal frame 26 before separating the lead frame 20.

After the light-emitting device 2 is formed, the first region 20a, the second region 20b and the third region 20c of the lead frame 20 are separated from the metal frame 26 respectively along cut sections 27a, 27b and 27c indicated by dotted-lines in FIG. 4B.

As shown in FIG. 4B, the cut sections 27a and 27b of the lead frame 20 are positioned at edges of the lead frame 20 in the longitudinal direction (in the width direction of the light-emitting device 2) to prevent an increase in the depth of the light-emitting device 2.

However, the cut section 27c for the third region 20c located between the first region 20a and the second region 20b has to be positioned at an edge of the lead frame 20 in the shorter direction (i.e., in the depth direction of the light-emitting device 2). Therefore, in order to prevent an increase in the depth of the light-emitting device 2, a recessed portion 22 is provided on the third region 20c which thus has a shape such that a protrusion in the vicinity of the cut section 27c is located within the recessed portion 22.

The third region 20c with the recessed portion 22 is reduced in depth by the recessed portion 22 and, therefore, the light-emitting elements 12 and 13 are difficult to mount at both ends of the third region 20c in the shorter direction. Thus, the light-emitting elements 12 and 13 are each connected to both ends of the third region 20c in the longer direction without the recessed portion 22, as shown in FIGS. 3 and 4A.

By contrast, the light-emitting device 1 of the present embodiment uses the conductive paste film 14 as a relay area between the first region 10a and the second region 10b of the lead frame 10, instead of using the lead frame 20. It is obvious that, unlike the lead frame 20, the recessed portion is not needed to form in the conductive paste film 14 and the entire conductive paste film 14 has a sufficient width to mount the light-emitting elements 12 and 13. As a result, it is possible to mount the light-emitting element 12 close to the light-emitting element 13, allowing the light-emitting device 1 to have a smaller width than the light-emitting device 2.

### Method of Manufacturing Light-Emitting Device

An example of a method of manufacturing the light-emitting device 1 in the present embodiment will be described below.

Firstly, the lead frame 10, which is included in the metal frame 16 and has the first region 10a and the second region 10b, is integrally molded into the case 11 having the recessed portion 18 by insert molding, etc. The first region 10a and the second region 10b are exposed on the bottom of the recessed portion 18 of the molded case 11.

Next, the conductive paste film 14 is formed on the bottom of the recessed portion 18 of the molded case 11 in a region between the first region 10a and the second region 10b.

Next, the flip-chip light-emitting element 12 is mounted so that the electrodes 12c and 12d thereof are respectively electrically connected to the first region 10a and the conductive paste film 14. Likewise, the flip-chip light-emitting element 13 is mounted so that the electrodes 13d and 13c thereof are respectively electrically connected to the second region 10b and the conductive paste film 14.

Next, the sealing material 19 is formed in the recessed portion 18 of the case 11 so that the light-emitting elements 12 and 13 are sealed. The sealing material 19 is formed by potting, etc.

Next, the first region 10a and the second region 10b of the lead frame 10 are separated from the metal frame 16 respectively at the cut sections 17a and 17b.

### EFFECTS OF THE EMBODIMENT

In the embodiment, since the thin light-emitting device 1, which is provided with plural light-emitting elements 12 and 13 mounted in the case 11 molded integrally with the lead frame 10, uses the conductive paste film 14 as a relay area for series connection of the lead frame 10 and the light-emitting elements 12 and 13, the size of the light-emitting device 1 can be reduced relative to the light-emitting elements 12 and 13.

Although the embodiment of the invention has been described, the invention is not intended to be limited to the embodiment and the various kinds of modifications can be implemented without departing from the gist of the invention.

In addition, the invention according to claims is not to be limited to the embodiment. Further, all combinations of the features described in the embodiment are not needed for solving the problem of the invention.

What is claimed is:

1. A light-emitting device, comprising:
a case comprising a recessed portion;
a lead frame that is integrally molded with the case so as to be exposed on a bottom of the recessed portion and that comprises separated first and second regions;
a conductive paste film formed on the bottom of the recessed portion in a region between the first and second regions;
a first flip-chip light-emitting element comprising first and second electrodes that are electrically connected to the first region and the conductive paste film, respectively; and
a second flip-chip light-emitting element comprising third and fourth electrodes that are electrically connected to the second region and the conductive paste film, respectively.

2. The light-emitting device according to claim 1, wherein the first electrode is connected to the first region and the third electrode to the second region via the conductive paste film, and
wherein the second and fourth electrodes are directly connected to the conductive paste film.

3. The light-emitting device according to claim 1, wherein the case comprises a thermoplastic resin.

4. The light-emitting device according to claim 1, wherein a rugged pattern is formed on the bottom of the recessed portion in a region in contact with the conductive paste film.

5. A method of manufacturing a light-emitting device, comprising:
molding a case comprising a recessed portion integrally with a lead frame included in a metal frame and comprising separated first and second regions such that the first and second regions are exposed on a bottom of the recessed portion;
forming a conductive paste film on the bottom of the recessed portion in a region between the first and second regions;
mounting a first flip-chip light-emitting element comprising first and second electrodes such that the first and second electrodes are electrically connected to the first region and the conductive paste film, respectively;
mounting a second flip-chip light-emitting element comprising third and fourth electrodes so that the third and fourth electrodes are electrically connected to the second region and the conductive paste film, respectively; and
separating the first and second regions of the lead frame from the metal frame.

6. The method according to claim 5, wherein the mounting of the first and second flip-chip light-emitting elements is conducted such that the first electrode is connected to the first region and the third electrode to the second region via conductive paste and the second and fourth electrodes are directly connected to the conductive paste film.

7. The method according to claim 5, wherein the case comprises a thermoplastic resin.

8. The method according to claim 5, wherein a rugged pattern is formed on the bottom of the recessed portion in a region in contact with the conductive paste film.
